(19) United States
(12) Patent Application Publication
(10) Pub. No.: US 2010/0178490 A1
(43) Pub. Date: Jul. 15, 2010

(54) ROLL-TO-ROLL PLASMA ENHANCED CHEMICAL VAPOR DEPOSITION METHOD OF BARRIER LAYERS COMPRISING SILICON AND CARBON

(76) Inventors: Glenn Cerny, Midland, MI (US); Mark Loboda, Bay City, MI (US); Vasgen Shamamian, Midland, MI (US); Steven Snow, Sanford, MI (US); William Weidner, Bay City, MI (US); Ludmil Zambov, Midland, MI (US)

Correspondence Address: WILLIAMS, MORGAN & AMERSON, 10333 RICHMOND, SUITE 1100, HOUSTON, TX, 77042, US

(21) Appl. No.: 12/529,393

(22) PCT Filed: Feb. 29, 2008
(86) PCT No.: PCT/US2008/055436

§ 371 Date: Mar. 8, 2010

Related U.S. Application Data
(60) Provisional application No. 60/908,498, filed on Mar. 28, 2007.

(51) Int. Cl. B32B 27/06; C23C 16/44; C23C 16/32; B32B 9/04; B32B 3/26

(52) U.S. Cl. 428/315.5; 427/569; 427/571; 427/577; 428/446

(57) ABSTRACT

The present invention provides method and process for forming a barrier layer on a flexible substrate. The continuous roll-to-roll method includes providing a substrate to a processing chamber using at least one roller configured to guide the substrate through the processing chamber. The process includes depositing a barrier layer adjacent the substrate by exposing at least one portion of the substrate that is within the processing chamber to plasma comprising a silicon-and-carbon containing precursor gas. The present invention is further directed to a coated flexible substrates comprising a barrier layer based on the structural unit SiC:H. The barrier layer possesses high density and low porosity. Still further, the barrier layer exhibits low water vapor transmission rate (WVTR) in the range of 10⁻²-10⁻³ g.m⁻²d⁻¹ and is appropriate for very low permeability applications.

### BACKGROUND OF THE INVENTION

1. Field of the Invention

This invention relates generally to deposition of barrier layers, and, more particularly, to roll-to-roll plasma enhanced chemical vapor deposition of a barrier layer comprising silicon and carbon.

2. Description of the Related Art

Barrier layers are commonly used to provide protection from a wide variety of potentially damaging conditions in the environment. For example, hydrophobic barrier layers may be used to provide protection from water, opaque barrier layers may be used to provide protection against various types of radiation, scratch-resistant barrier layers may be used to provide protection from abrasion, and the like. Barrier layers may be used as protection against moisture and oxygen in drug and food packaging as well as in numerous flexible electronic devices, including liquid crystal and diode displays, photovoltaic and optical devices (including solar cells) and thin film batteries. Barrier layers are typically formed on a substrate, such as a flexible plastic films or a metal foil.

Films of hydrogenated silicon oxycarbide suitable for use as interlayer dielectrics or environmental barriers, and methods for producing such films are known in the art. For example, U.S. Pat. No. 6,159,871 to Loboda et al. describes a chemical vapor deposition method for producing hydrogenated silicon oxycarbide films. The CVD method described in Loboda includes introducing a reactive gas mixture comprising a methyl-containing silane and an oxygen-providing gas into a deposition chamber containing a substrate. A reaction is induced between the methyl-containing silane and oxygen-providing gas at a temperature of 25° C. to 500° C. There is a controlled amount of oxygen present during the reaction, which creates film comprising hydrogen, silicon, carbon and oxygen having a dielectric constant of 3.6 or less on the substrate.

International Application Publication No. WO 02/054484 to Loboda describes an integrated circuit including a subassembly of solid state devices formed into a substrate made of a semiconducting material. The integrated circuit also includes metal wiring connecting the solid state devices. A diffusion barrier layer is formed on at least the metal wiring and the diffusion barrier layer is an alloy film having a composition of SiwCxOyHz, where w has a value of 10 to 33, x has a value of 1 to 66, y has a value of 1 to 66, z has a value of 0.1 to 60, and w+x+y+z=100 atomic %.

U.S. Pat. No. 6,593,655 to Loboda et al. describes a semiconductor device that has a film formed thereon. The film is produced by introducing a reactive gas mixture comprising a methyl-containing silane and an oxygen providing gas into a deposition chamber containing a semiconductor device and inducing a reaction between the methyl-containing silane and oxygen-providing gas at a temperature of 25° C. to 500° C. A controlled amount of oxygen is present during the reaction, which creates a film comprising hydrogen, silicon, carbon and oxygen having a dielectric constant of 3.6 or less on the semiconductor device.

U.S. Pat. No. 6,667,553 to Cerny et al. describes a substrate, such as a liquid crystal device, a light emitting diode display device, and an organic light emitting diode display device. A film is produced on the substrate by introducing a reactive gas mixture comprising a methyl-containing silane and an oxygen-providing gas into a deposition chamber containing the substrate. A reaction is induced between the methyl-containing silane and oxygen-providing gas at a temperature of 25° C. to 500° C. A controlled amount of oxygen is present during the reaction, which creates a film comprising hydrogen, silicon, carbon and oxygen having a dielectric constant of 3.6 or less on the substrate. The film has a light transmittance of 95% or more for light with a wavelength in the range of 400 nm to 800 nm.

United States Patent 20030215652 to P. O'Connor describes a polymeric container having a plasma-polymerized surface of an organic-containing layer of the formula SiOxCyHz. The plasma-formed barrier system may be a continuous plasma-deposited coating that has a composition that varies from the formula SiOxCyHz at the interface between the plasma layer and the polymeric container's original surface to SiOx at the surface that has become the new surface of the container in the course of the deposition process. The continuum is formed by initiating plasma in the absence of an oxidizing compound, then adding an oxidizing compound to the plasma. The concentration of the oxidizing compound is increased to a concentration that is sufficient to oxidize the precursor monomer. Alternatively, a barrier system having a continuum of composition from the substrate interface may form a dense, high-barrier portion by increasing the power density and/or the plasma density without a change of oxidizing content. Further, a combination of oxygen increase and increased power density/plasma density may develop the dense portion of the gradient barrier system.

Conventional deposition processes such as those described above use batch processing to deposit barrier layers on substrates. However, batch processing is not a continuous technique and typically requires loading the substrate into a process chamber, forming the barrier layer over the substrate, and then removing the substrate with the barrier layer formed thereon from the process chamber. Once the substrate has been removed from the process chamber, then another substrate may be placed in the process chamber so that the barrier layer may be formed on the new substrate. The time required to insert and/or remove the substrates from the chambers may increase the overall processing time required to form a barrier layer and reduce the production volume of the system.

Patent application WO 02/086185 A1 to J. Madocks relates to a Penning discharge plasma source that can be implemented in a continuous roll-to-roll method. The magnetic and electric field arrangement, similar to a Penning discharge, effectively traps the electron Hall current in a region between two surfaces. When a substrate is positioned proximate to at least one of the electrodes and is moved relative to the plasma, the substrate is plasma treated, coated or otherwise modified depending upon the process conditions.

The present invention is directed to addressing the effects of one or more of the problems set forth above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one embodiment of the present invention, a method is provided for forming a barrier layer on a substrate. The method, defined as continuous roll-to-roll processing, includes providing a substrate to a processing chamber using at least one roller configured to guide the substrate through the processing chamber. The method also includes depositing a barrier layer adjacent the substrate by exposing at least one portion of the substrate that is within the processing chamber to plasma comprising a silicon-and-carbon containing precursor gas.

In another embodiment of the present invention, a barrier layer is formed on a substrate according to a process. The process includes providing the substrate to a processing chamber using at least one roller configured to guide the substrate through the processing chamber. The process, defined as Plasma Enhanced Chemical Vapor Deposition (PECVD), also includes depositing the barrier layer adjacent the substrate by exposing at least one portion of the substrate that is within the processing chamber to plasma comprising a silicon-and-carbon containing precursor gas.

In yet another embodiment of the present invention, an apparatus is provided for forming a barrier layer on a substrate. The apparatus includes a processing chamber configured to receive at least one portion of a substrate and expose said at least one portion of the substrate to plasma. The apparatus also includes at least one roller for guiding the substrate through the processing chamber so that a barrier layer is deposited adjacent the substrate by exposure to the silicon-and-carbon containing precursor gas.

In yet another embodiment of the present invention, a method is provided for forming a barrier layer on a substrate. The method includes guiding, using at least one roller, a substrate having a length, L, through a processing chamber containing plasma formed of a silicon-and-carbon containing precursor gas, with or without the addition of an inert gas and/or oxidizing reagent. The method also includes depositing a barrier layer adjacent a surface of the substrate at a selected portion of the substrate along the length, L, as the substrate is guided through the processing chamber.

The barrier layer described in the present invention has higher density and lower porosity than conventional hydrogenated silicon carbide or oxycarbide films. The barrier layer has a low water vapor transmission rate, typically in the range of 10⁻²-10⁻³ gm⁻²d⁻¹.

### BRIEF DESCRIPTION OF THE DRAWINGS

The invention may be understood by reference to the following description taken in conjunction with the accompanying drawings, in which like reference numerals identify like elements, and in which:

FIG. 1 conceptually illustrates one exemplary embodiment of a reactor system that may be used to deposit barrier layers using a roll-to-roll technique, in accordance with the present invention;

FIG. 2 shows a cross-sectional view of a coated substrate according to the present invention.

FIG. 3 depicts the FTIR the barrier coatings formed in accordance with the present invention;

FIG. 4 presents the optical transmission of barrier coatings formed in accordance with the present invention;

FIG. 5 depicts optical transmission of silicon carbide-based barrier coatings as a function of the oxygen content in the gas phase;

FIG. 6 depicts the optical transmission of silicon carbide-based barrier layers as a function of electrical power in the reactor system;

Table 1 summarizes the process parameters and properties of the barrier coatings from examples 1-4. Water permeability tests have been performed at 38° C. and 100% relative humidity (RH).

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions should be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

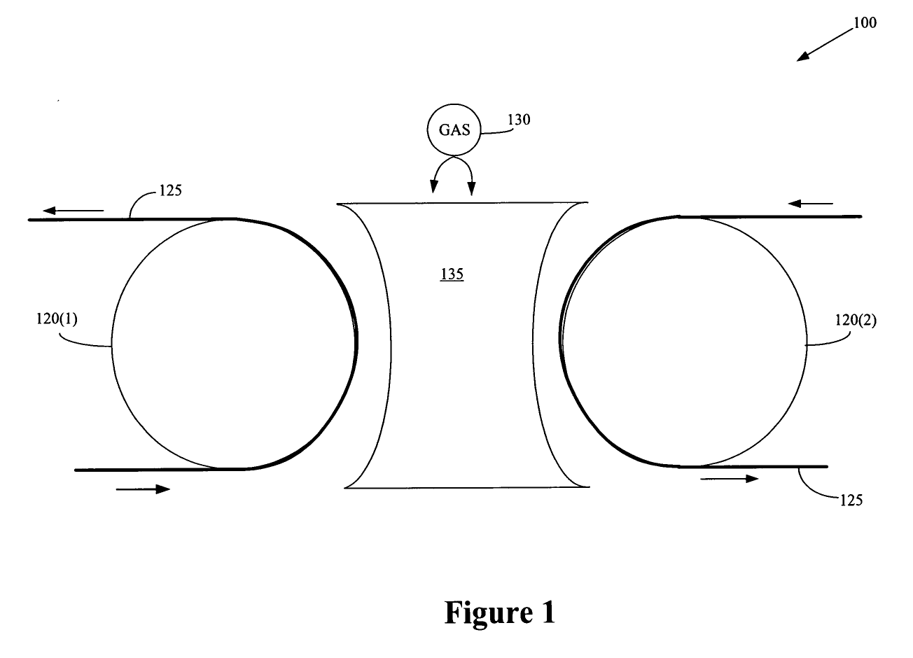

FIG. 1 conceptually illustrates one exemplary embodiment of a reactor system 100 that may be used to deposit barrier layers using a roll-to-roll technique. In the illustrated embodiment, the reactor system 100 is used to implement a continuous roll-to-roll plasma method of preparing coated flexible plastic substrates that are impermeable to water vapor. Roll to roll manufacturing is a process where a roll, or web, runs through a process machine using rollers to define the path of the web and maintain proper tension and position of the web. Thus, this technique is sometimes called “web processing.” The web is typically a large continuous roll of flexible plastic or metal foil material that serves as a substrate for the barrier layer. As the substrate passes through the process chamber(s), chemicals are introduced and functional layers are created. In the illustrated present embodiment, the reactor system 100 includes a process chamber (not shown). Persons of ordinary skill in the art having benefit of the present disclosure will appreciate that in the interest of clarity only the features of the reactor system and the process chamber that are relevant to the present invention are depicted in FIG. 1 and described herein.

Two rollers 120(1-2) may be used to provide portions of a flexible substrate 125 to the process chamber. The flexible substrate 125 may be a plastic substrate or a metal foil. In alternative embodiments, the plastic film substrate 125 may be formed of a polyethylene naphthalate (PEN), a polyethylene terephthalate (PET), polyester, polyethersulfone, polycarbonate, polyimide, polyfluorocarbon, and the like. The rollers 120 are also coupled to a voltage source (not shown) that may be used to establish a voltage difference between the rollers 120 and chamber walls. For example, the rollers 120 may act as a cathode or as an anode so that an electric field is formed in the process chamber. In the preferred embodiment, additional rollers may also be provided to guide the substrate 125 and/or to adjust or maintain the tension in the substrate 125. However, persons of ordinary skill in the art having benefit of the present disclosure should appreciate that the present invention is not limited to the particular number and/or configuration of rollers 120 shown in FIG. 1. In alternative embodiments, more or fewer rollers 120 may be used to provide the portions of the substrate 125 to the process chamber. In one embodiment, the rollers 120 may be temperature-controlled.

A gas source 130 is used to provide one or more gases to the process chamber. Although a single gas source 130 is depicted in FIG. 1, persons of ordinary skill in the art having benefit of the present disclosure should appreciate that the present invention is not limited to a single gas source 130. In alternative embodiments, any number of gas sources 130 may be used to provide gases to the process chamber. In one embodiment, a gas source 130 provides gases containing silicone and carbon, such as organosilanes, to the process chamber. The gas source 130 may also provide hydrogen and/or oxygen, as well as one or more inert gases, such as argon and/or helium. For example, the gas source 130 may provide a gas mixture consisting of trimethylsilane ((CH₃)₃SiH) as a silicon-carbon containing precursor, with or without argon as an inert gas. Gases in the process chamber may be ionized to form plasma 135 within the process chamber. The plasma 135 may then be confined in the process chamber by a magnetic field. This type of plasma source is commonly referred to as a Penning discharge plasma source.

In operation, the substrate 125 passes over the roller 120(2) into the process chamber, exposing one side of the substrate 125 to the plasma in the process chamber. A barrier layer may then be deposited on the substrate 125 while it is exposed to the plasma. For example, a barrier layer may be deposited on the portion of the substrate 125 that it is exposed to the plasma as the substrate 125 is guided through the process chamber by the rollers 120. For example, if the plasma is formed from a gas including silicon, carbon, and hydrogen, a non-gradient barrier layer may be formed of hydrogenated silicon carbide based on the structural unit SiC:H. For another example, if the plasma is formed from a gas including silicon, carbon, hydrogen, and oxygen, a barrier layer may be formed of hydrogenated silicon oxycarbide based on the structural unit SiOC:H. The substrate 125 may then pass out of the process zone 150, over the additional rollers, and be guided back into the process zone by another roller 120(2), where it is again exposed to the plasma in the process chamber so that additional portions of the barrier layer may be formed. In this way a continuous barrier coated plastic film can be manufactured.

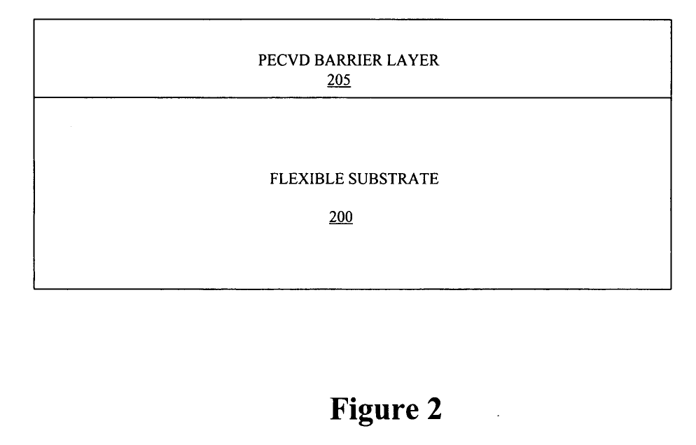

FIG. 2 shows a cross-sectional view of a coated substrate 200. In the illustrated embodiment, a barrier layer 205 has been deposited over the flexible substrate 200. For example, the barrier layer 205 may be deposited using plasma enhanced chemical vapor deposition (PECVD), as discussed herein.

Referring back to FIG. 1, operating parameters of the reactor system 100, such as the web speed (or roller speed), plasma power, gas pressures, concentrations and/or flow rates, may be adjusted to achieve certain properties of the barrier layer. In one embodiment, the operating parameters may be adjusted so that the barrier layer has a relatively high density and low nanoporosity compared to conventional hydrogenated silicon carbide and/or siloxane films. For example, the low plasma impedance of the plasma in a Penning discharge plasma source allows the reactor system 100 to operate at low pressures. By operating in the low mTorr range (<50 mTorr), the mean free path of gas species is long enough to minimize the gas phase chemical interactions and particles formation. This permits higher monomer delivery and deposition rates (e.g., dynamic deposition rates of up to 200 nm.m/min) of quality deposit of the barrier layer by applying plasma powers in the range of 300-400 W.

The properties of barrier layers formed using the techniques described herein may be determined applying various types of metrology. Exemplary metrology techniques include determining the thickness and thickness uniformity of the barrier layer using a Tristan spectrometer; analyzing barrier layer performance using a MOCON Permatran-W permeation test system and/or the conventional Ca test, determining optical properties of the barrier layer via UV-VIS spectrometry performed with a Shimadzu UV 2401 PC spectrometer, determining the composition of the barrier layer using energy dispersion analysis of X-rays (EDAX), Rutherford backscattering spectroscopy (RBS) and Fourier transformed InfraRed (FTIR) spectroscopy, determining the surface wetability by optical measurement of the water contact angle of the barrier layer, determining the adhesion properties of the barrier layer by the standard tape test, determining the scratch resistance of the barrier layer by applying the Steelwool test, determining the film surface roughness of the barrier layer using atomic force microscopy (AFM) in tapping mode with Veeco's Dimension 5000 AFM, determining thermal stability using the conventional boiling water test, as well as using a scanning electron microscope (SEM) and/or optical microscope examinations.

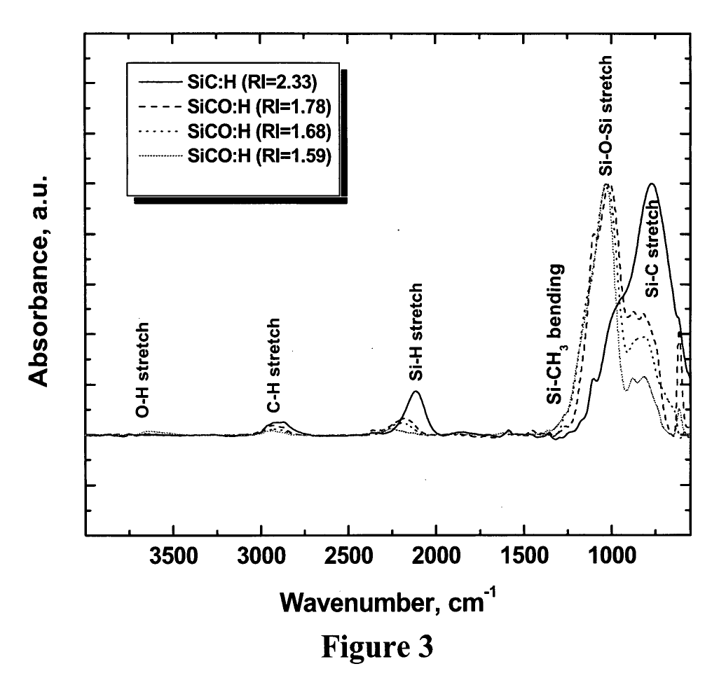

FIG. 3 depict the Fourier transformed infrared (FTIR) spectra of embodiments of barrier layers formed using embodiments of the techniques described herein. The IR absorption of the barrier layers are plotted as a function of the wave number in cm⁻¹. In the embodiments illustrated in FIG. 3, the barrier coatings are formed of hydrogenated silicon carbide based on the structural unit SiC:H or hydrogenated silicon oxycarbide based on the structural unit SiOC:H. The IR absorption show peaks corresponding to various chemical bond oscillations of the barrier layer material, such as bending modes and stretching modes. The FTIR spectra of the barrier layers deposited at static conditions (FIG. 3) indicate typical SiC-based bonding structure with reduced hydrogen content, which is a characteristic of High Density Plasma (HDP) processes. Also shown in FIG. 3 (legend frame) are the corresponding refractive index (RI) values of coatings as measured by spectroscopic ellipsometry.

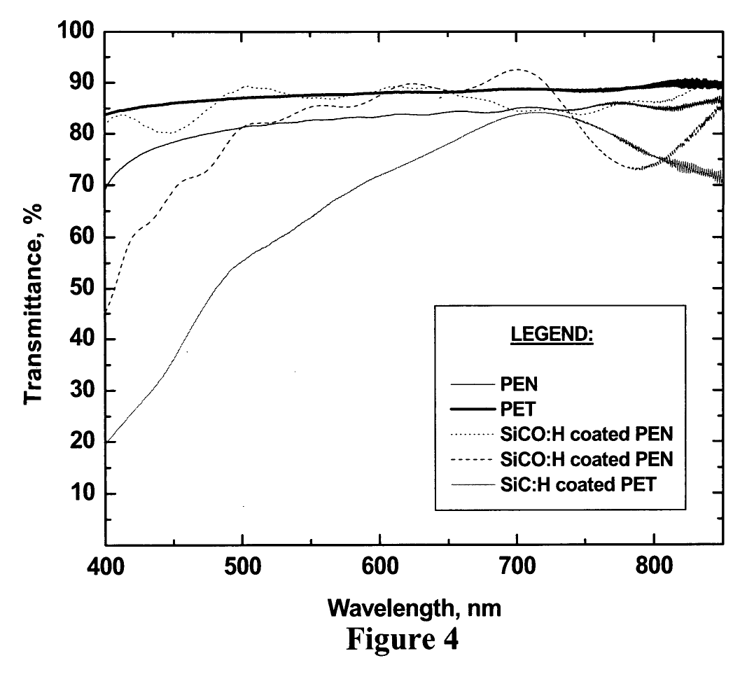

Barrier coatings formed on flexible plastic substrates in this manner have low water vapor transmission rates (WVTR) that are in the range of 10⁻²-10⁻³ g.m⁻²d⁻¹, as it has been determined by the Permatran-W permeability tester from Mocon Inc., and by the calcium (Ca) degradation test performed in Dow Corning Co. The barrier layers are also highly hydrophobic, e.g. the water contact angle of the barrier layers may be above 85°. The thickness of the deposited barrier layers may also depend on the web speed and the speed is typically adjusted so that the barrier layer thickness is between 0.5 and 2.0 μm. Further, the silicon carbide barrier layers are smooth. Depending on the thickness of the barrier layer, root mean square roughness (rms) is in the limits of 2-6 nm, as has been determined by atomic force microscopy (AFM). The barrier layers are transparent, typically at least 55% for light in the visible region of the electromagnetic spectrum as indicated from the ultraviolet-visual spectra of blank substrates and substrates coated with a barrier layer depicted in FIG. 4. In the illustrated embodiment, the transmittance percentage is plotted on the vertical axis and the light wavelength in nanometers is plotted on the horizontal axis. The lines depict the transmittance for a blank PEN substrate, a blank PET substrate, and substrates coated with hydrogenated silicon carbide-based barrier layers. The transmittance typically increases with increasing wavelength and fall within the range of approximately 70-90%. Moreover, the transparency of the barrier layers may be improved by oxygenation. Silicon oxycarbide barrier layers may have a transparency of at least 80% for light in the visible region of the electromagnetic spectrum as indicated from FIG. 4 (dash and dotted lines).

The barrier layers formed using the techniques described herein can be used as protection against moisture and oxygen in food, beverage and drug packaging as well as in numerous flexible electronic devices including liquid crystal and diode displays, photovoltaic and optical devices (including solar cells) and thin film batteries.

### EXAMPLES

The following examples are presented to better illustrate the coated substrates and methods of the present invention. However, these examples are intended to be illustrative and not to limit the present invention. In the examples, barrier coating deposition has been performed utilizing a single- and/or dual-asymmetric Penning discharge plasma source that operates in the medium frequency range. The temperature of the rollers in the deposition chamber has been maintained at 18-25° C. Tables 1 and 2 present some of the physical properties of the barrier layers formed according to the present examples and FIGS. 4, 5 and 6 present some of the optical properties of the barrier layers.

### Examples 1 and 2

Barrier coating deposition has been performed at a plasma power range of 300-500 W (Table 1). The deposition process has been conducted introducing a silicon-carbon containing precursor, namely trimethylsilane ((CH₃)₃SiH), in the deposition chamber or a reactive gas mixture comprising trimethylsilane ((CH₃)₃SiH), and argon (Ar) with gas flow rate ratios of Ar/((CH₃)₃SiH) up to 2.5 at a pressure range of 20-30 mTorr (Table 1). Barrier coatings have been deposited on polyethylenterephtalate (PET) film material. The thickness of the deposited barrier layers is typically around 0.75 μm. Barrier coatings contain silicon (Si), carbon (C), oxygen (O) as contaminant and hydrogen (H) in compositional ratios of Si/C=0.60-0.65 and O/Si=0.075-0.10, i.e. the material can be classified as hydrogenated silicon carbide based on the structural unit SiC:H (Table 1, FIG. 3—solid line). Barrier layer has a low water vapor transmission rate (WVTR), in the range of 10⁻³-10⁻² g.m⁻²d⁻¹, as it has been determined by the Permatran-W permeability tester from Mocon Inc. Barrier layers are smooth and well-adhered. The barrier layers could be highly absorbent in the 400 nm range of the visible light spectrum and the coated plastic substrates possess transparency, typically more than 50% for the visible light at a wavelength of 600 nm and above (FIG. 4, solid grey line).

### Examples 3 and 4

Barrier coating deposition has been performed at the power range of 250-300 W (Table 1). The deposition process has been conducted introducing a reactive gas mixture in the deposition system comprising silicon-carbon containing precursor, namely trimethylsilane ((CH₃)₃SiH), argon (Ar) and oxygen (O₂) with gas flow ratios of Ar/((CH₃)₃SiH)=1.0-1.5 and O₂/((CH₃)₃SiH)=0.5-1.25 at a pressure range of 30-50 mTorr (Table 1). In this example, the barrier layer has been deposited on both PET and PEN flexible substrates. The thickness of the deposited barrier is typically in the range of 1.5-2.0 μm. Barrier coating contains silicon (Si), carbon (C), oxygen (O) and hydrogen (H) in compositional ratios of Si/C=0.95-1.10 and O/Si=0.35-1.0, i.e. the material can be classified as hydrogenated silicon oxycarbide based on the structural unit SiOC:H (Table 1, FIG. 3—dash and dotted lines). Barrier layers have low water vapor transmission rate (WVTR), in the range of 10⁻³ g.m⁻²d⁻¹, as it has been determined by the Permatran-W permeability tester from Mocon Inc. Barrier coatings are smooth—the root mean square roughness (rms) is in the limits of 4-6 nm. The coated plastic substrates possess transparency, typically more than 75% for the visible light at a wavelength of 500 nm and above (FIG. 4, dash and dotted lines). Further, the barrier layers are well adhered to the plastic substrates and withstand the standard tape test. Still further, the coated plastic substrates, respectively the barrier layers withstand the boiling water test.

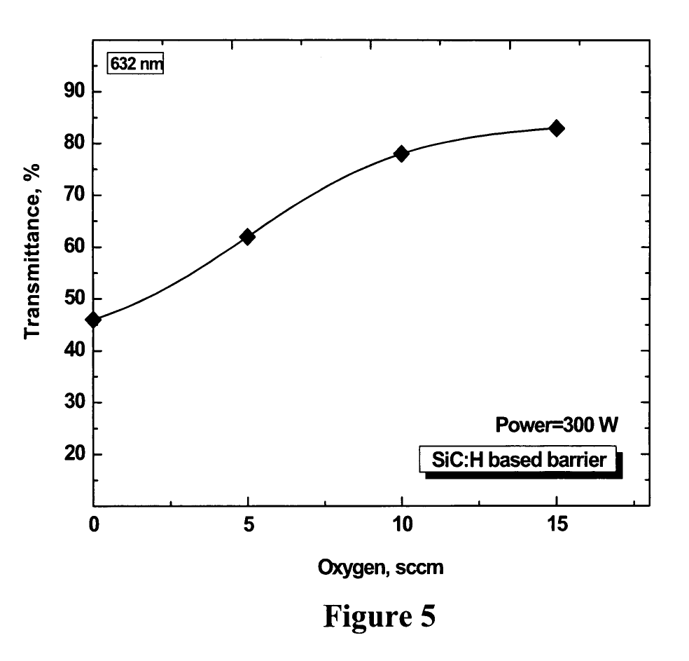

FIG. 5 depicts optical transmission of oxygen-doped silicon carbide-based barrier layers on plastic substrate as a function of the oxygen content in the gas phase. In the illustrated embodiment, the transmittance of the barriers is plotted on the vertical axis as a function of the oxygen flow rate, which is plotted on the horizontal axis. The refractive index of the barrier layers tends to fall with increasing oxygen content and the transmittance of the barriers tends to increase with increasing the oxygen content.

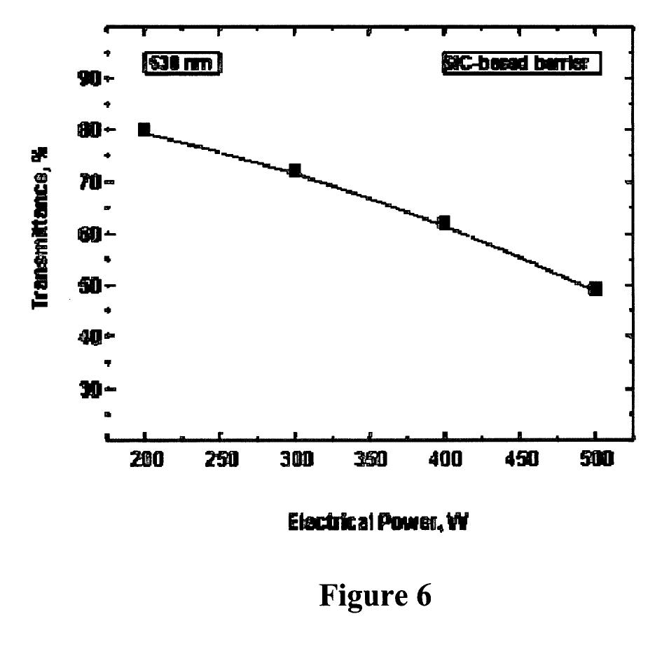

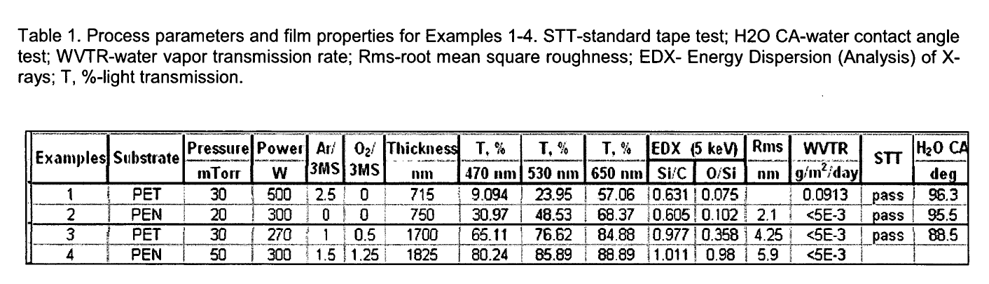

FIG. 6 depicts optical transmission of oxygen-doped silicon carbide-based barrier layers on plastic substrate as a function of the electrical power in the reactor system. In the illustrated embodiment, the transmittance of the barriers is plotted on the vertical axis as a function of the applied electrical power in Watts, which is plotted on the horizontal axis. The transmittance of the barrier layers tends to fall with the increment of the applied electrical power.

Roll-to-roll deposition of barrier layers comprising silicon, carbon, hydrogen, and/or oxygen may be a very effective technique for forming barrier coated films, such as barrier plastics that may be utilized in flexible electronic devices. For example, embodiments of the trimethylsilane PECVD barrier technology described herein have been tested and successfully adapted using roll-to-roll coating system. The barrier layer deposition techniques described herein exhibit a wide range of tunability with respect to process operating conditions and barrier properties and a dynamic deposition rate up to 150 nm.m/min has been realized. Due to the energy input provided by the Penning Discharge Plasma Source, “soft” process conditions (plasma power between 200 and 300 W) may be established. Soft process conditions may be particularly appropriate for deposition of stress-reduced, crack-resistant and transparent coatings with a high level of barrier protection, namely WVTR<10⁻³ g.m⁻²d⁻¹ and barrier improvement factor BIF>1000.

The particular embodiments disclosed above are illustrative only, as the invention may be modified and practiced in different but equivalent manners apparent to those skilled in the art having the benefit of the teachings herein. Furthermore, no limitations are intended to the details of construction or design of the equipment, other than as described in the claims below. It is therefore evident that the particular embodiments disclosed above may be altered or modified and all such variations are considered within the scope of the invention. Accordingly, the protection sought herein is as set forth in the claims below.

What is claimed:

1. A method, comprising:
providing a substrate to a processing chamber using at least one roller configured to guide the substrate through the processing chamber; and
depositing a barrier layer adjacent the substrate by exposing at least one portion of the substrate that is within the processing chamber to a plasma comprising a silicon-and-carbon containing precursor gas.

2. The method of claim 1, wherein providing the substrate to the processing chamber comprises providing a flexible web substrate to the processing chamber.

3. The method of claim 2, wherein providing the flexible web substrate to the processing chamber comprises providing a flexible web substrate formed of at least one of a polyethylene naphthalate plastic film and a polyethylene terephthalate plastic film to the processing chamber.

4. The method of claim 1, wherein providing the substrate to the processing chamber comprises providing a substrate having a length dimension that is longer than the linear dimensions of the processing chamber and a width dimension that is smaller than or approximately equal to at least one linear dimension of the processing chamber.

5. The method of claim 1, wherein providing the substrate to the processing chamber using at least one roller comprises providing the substrate to the processing chamber using a plurality of rollers configured to maintain a selected tension in the substrate and a selected position of the substrate.

6. The method of claim 5, wherein providing the substrate to the processing chamber using the plurality of rollers comprises providing the substrate to the processing chamber using the plurality of rollers such that a first portion of the substrate is exposed to the plasma proximate a first side of the processing chamber and a second portion of the substrate is concurrently exposed to the plasma proximate a second side of the processing chamber, the first side being opposite the second side.

7. The method of claim 1, wherein exposing the portion of the substrate to the plasma comprises exposing the portion of the substrate to magnetically confined plasma.

8. The method of claim 7, wherein exposing the portion of the substrate to the magnetically confined plasma comprises exposing the portion of the substrate to magnetically confined plasma formed by a Penning discharge plasma source.

9. The method of claim 8, wherein exposing the portion of the substrate to the plasma comprising the silicon-and-carbon containing precursor gas comprises exposing the portion of the substrate to plasma comprising trimethylsilane precursor gas.

10. The method of claim 9, wherein exposing the portion of the substrate to the plasma comprising the silicon-and-carbon containing precursor gas comprises exposing the portion of the substrate to the plasma comprising the silicon-and-carbon containing precursor gas and an inert gas, such as argon.

11. The method of claim 10, wherein exposing the portion of the substrate to the plasma comprising the silicon-and-carbon containing precursor gas comprises exposing the portion of the substrate to the plasma comprising the silicon-and-carbon containing precursor gas, an inert gas and oxidant such as oxygen.

12. The method of claim 1, wherein depositing the barrier layer comprises depositing a barrier layer comprised of hydrogenated silicon carbide based on the structural unit SiC:H.

13. The method of claim 12, wherein depositing the barrier layer comprises depositing a single barrier layer comprised of hydrogenated silicon carbide based on the structural unit SiC:H has high density, low porosity and low water vapor transmission rate and is appropriate for very low permeability applications.

14. The method of claim 1, wherein depositing the barrier layer comprises depositing a barrier layer comprised of hydrogenated silicon oxycarbide based on the structural unit SiOC:H.

15. The method of claim 14, wherein depositing the barrier layer comprises depositing a single barrier layer comprised of hydrogenated silicon carbide based on the structural unit SiOC:H that has high density, low porosity and low water vapor transmission rate and is appropriate for very low permeability applications

16. The method of claim 1, wherein providing the substrate to the processing chamber and depositing the barrier layer comprises providing the substrate to the processing chamber and depositing the barrier layer according to at least one operating parameter selected based upon at least one of a target barrier layer thickness and a target barrier layer nanoporosity.

17. A barrier layer formed on a substrate by a process comprising:
providing the substrate to a processing chamber using at least one roller configured to guide the substrate through the processing chamber; and
depositing the barrier layer adjacent the substrate by exposing at least one portion of the substrate that is within the processing chamber to a plasma comprising a silicon-and-carbon containing precursor gas.

18. The barrier layer formed on the substrate by the process of claim 17, wherein providing the substrate to the processing chamber comprises providing a flexible web substrate to the processing chamber.

19. The barrier layer formed on the substrate by the process of claim 18, wherein providing the flexible web substrate to the processing chamber comprises providing a flexible web substrate formed of at least one of a polyethylene naphthalate plastic film and a polyethylene terephthalate plastic film to the processing chamber.

20. The barrier layer formed on the substrate by the process of claim 17, wherein providing the substrate to the processing chamber comprises providing a substrate having a length dimension that is longer than the linear dimensions of the processing chamber and a width dimension that is smaller than or approximately equal to at least one linear dimension of the processing chamber.

21. The barrier layer formed on the substrate by the process of claim 17, wherein providing the substrate to the processing chamber using at least one roller comprises providing the substrate to the processing chamber using a plurality of rollers configured to maintain a selected tension in the substrate and a selected position of the substrate.

22. The barrier layer formed on the substrate by the process of claim 21, wherein providing the substrate to the processing chamber using the plurality of rollers comprises providing the substrate to the processing chamber using the plurality of rollers such that a first portion of the substrate is exposed to the plasma proximate a first side of the processing chamber and a second portion of the substrate is concurrently exposed to the plasma proximate a second side of the processing chamber, the first side being opposite the second side.

23. The barrier layer formed on the substrate by the process of claim 17, wherein exposing the portion of the substrate to the plasma comprises exposing the portion of the substrate to magnetically confined plasma.

24. The barrier layer formed on the substrate by the process of claim 23, wherein exposing the portion of the substrate to the magnetically confined plasma comprises exposing the portion of the substrate to magnetically confined plasma formed by a Penning discharge plasma source.

25. The barrier layer formed on the substrate by the process of claim 17, wherein exposing the portion of the substrate to the plasma comprising the silicon-and-carbon containing precursor gas comprises exposing the portion of the substrate to plasma comprising trimethylsilane precursor gas.

26. The barrier layer formed on the substrate by the process of claim 25, wherein exposing the portion of the substrate to the plasma comprising the silicon-and-carbon containing precursor gas comprises exposing the portion of the substrate to the plasma comprising the silicon-and-carbon containing precursor gas and an inert gas, such as argon.

27. The barrier layer formed on the substrate by the process of claim 26, wherein exposing the portion of the substrate to the plasma comprising the silicon-and-carbon containing precursor gas comprises exposing the portion of the substrate to the plasma comprising the silicon-and-carbon containing precursor gas, an inert gas and oxidant such as oxygen.

28. The barrier layer formed on the substrate by the process of claim 17, wherein depositing the barrier layer comprises depositing a barrier layer comprised of hydrogenated silicon carbide based on the structural unit SiC:H.

29. The barrier layer formed on the substrate by the process of claim 17, wherein depositing the barrier layer comprises depositing a single barrier layer comprised of hydrogenated silicon carbide based on the structural unit SiC:H has high density, low porosity and low water vapor transmission rate and is appropriate for very low permeability applications.

30. The barrier layer formed on the substrate by the process of claim 17, wherein depositing the barrier layer comprises depositing a barrier layer comprised of hydrogenated silicon oxycarbide based on the structural unit SiOC:H.

31. The barrier layer formed on the substrate by the process of claim 17, wherein depositing the barrier layer comprises depositing a single barrier layer comprised of hydrogenated silicon carbide based on the structural unit SiOC:H that has high density, low porosity and low water vapor transmission rate and is appropriate for very low permeability applications

32. The barrier layer formed on the substrate by the process of claim 17, wherein providing the substrate to the processing chamber and depositing the barrier layer comprises providing the substrate to the processing chamber and depositing the barrier layer according to at least one operating parameter selected based upon at least one of a target barrier layer thickness and a target barrier layer nanoporosity.
